(19) United States
(12) Patent Application Publication
(10) Pub. No.: US 2024/0235724 A1
(43) Pub. Date: Jul. 11, 2024

(54) COMMUNICATION METHOD AND APPARATUS

(71) Applicant: HUAWEI TECHNOLOGIES CO., LTD., Shenzhen (CN)

(72) Inventors: Rong Li, Boulogne Billancourt (FR); Xianbin Wang, Hangzhou (CN); Huazi Zhang, Hangzhou (CN); Jiajie Tong, Hangzhou (CN); Jun Wang, Hangzhou (CN)

(73) Assignee: HUAWEI TECHNOLOGIES CO., LTD., Shenzhen (CN)

(21) Appl. No.: 18/614,675

(22) Filed: Mar. 24, 2024

Related U.S. Application Data
(63) Continuation of application No. PCT/CN2022/122888, filed on Sep. 29, 2022.

(30) Foreign Application Priority Data
Sep. 30, 2021 (CN) 202111157932.3

(51) Int. Cl. H04L 1/00

(52) U.S. Cl. CPC H04L 1/0013; H04L 1/0071

(57) ABSTRACT

This application provides a communication method and apparatus, and is applicable to the field of communication technologies, such as NR and LTE, to improve flexibility and diversity of channel coding, and improve communication performance and security. The method includes: A first device performs channel encoding on first data based on a generator matrix to obtain second data, and sends the second data to a second device. At least some parameters in the generator matrix are determined based on a random seed, and the random seed is determined based on one or more of the following: a channel encoding parameter, a parameter of the first device, or a parameter of the second device.

### CROSS-REFERENCE TO RELATED APPLICATIONS

This application is a continuation of International Patent Application No. PCT/CN2022/122888, filed on Sep. 29, 2022, which claims priority to Chinese Patent Application No. 202111157932.3, filed on Sep. 30, 2021. The disclosures of the aforementioned applications are hereby incorporated by reference in their entireties.

### TECHNICAL FIELD

This application relates to the communication field, and in particular, to a communication method and apparatus.

### BACKGROUND

Channel coding is a key technology in the communication field, and is used to protect data during data transmission and restore data when data errors occur. Generally, a structural code is used for channel coding, for example, a polar code, an RM (Reed Muller) code, a low-density parity-check (LDPC) code, or a BCH (Bose-Chaudhuri-Hocquenghem) code. A code structure of the structural code is designed. For example, a length of a mother code of each of the polar code and the RM code is 2^{m} bits, for example, 64 bits, 128 bits, or 256 bits, and a length of a mother code of the BCH code is 2^{m}−1 bits, for example, 7 bits, 15 bits, or 31 bits, where m is a positive integer, to facilitate decoding at a receive end.

### SUMMARY

Embodiments of this application provide a communication method and apparatus, to improve flexibility and diversity of channel coding and improve security.

The following technical solutions are used in this application:

According to a first aspect, a communication method is provided. The method includes: A first device performs channel encoding on first data based on a generator matrix to obtain second data, and sends the second data to a second device. At least some parameters in the generator matrix are determined based on a random seed, and the random seed is determined based on one or more of the following: a channel encoding parameter, a parameter of the first device, or a parameter of the second device.

It can be learned from the method according to the first aspect that the random seed is randomly determined, for example, determined based on one or more of the channel encoding parameter, the parameter of the first device, or the parameter of the second device, so that the at least some parameters determined based on the random seed are also random. The at least some parameters may be considered as random codes. In this way, performing channel encoding on the first data by using the random codes can improve flexibility and diversity of channel encoding, and improve communication performance and security.

In a possible design solution, the at least some parameters in the generator matrix are determined based on the random seed and a neural network.

In a possible design solution, the following relationship exists between the random seed and the parameter of the first device, the channel encoding parameter, and the parameter of the second device: seed=G[ƒ₁(x), ƒ₂(y), ƒ₃(z)], where seed is the random seed, x is the parameter of the first device, y is the parameter of the second device, z is the channel encoding parameter, G is a first function, ƒ₁ is a second function, ƒ₂ is a third function, and ƒ₃ is a fourth function. In other words, the random seed is obtained by performing a function operation on the parameter of the first device, the channel encoding parameter, and the parameter of the second device. This can improve randomness of the random seed, to further improve flexibility and diversity of channel encoding, and further improve security.

In a possible design solution, the at least some parameters are determined by processing the random seed according to one or more of the following algorithms: a square number algorithm or a chaos algorithm, to improve randomness of the at least some parameters, thereby further improving flexibility and diversity of channel encoding, and further improving security.

In a possible design solution, the generator matrix is a K*N matrix, K and N are positive integers, K is less than N, and a quantity of the at least some parameters is any one of K*(N−K), K*N, or N−K+1.

Optionally, the quantity of the at least some parameters is K*N, in other words, all parameters in the generator matrix are determined based on the random seed, to further improve randomness of the generator matrix, thereby further improving flexibility and diversity of channel encoding, and further improving security.

Alternatively, optionally, the quantity of the at least some parameters is K*(N−K), and K² parameters in the K*N parameters of the generator matrix other than the at least some parameters form an identity matrix, so that the generator matrix may be used for systematic code coding.

Alternatively, optionally, the quantity of the at least some parameters is N−K+1, and each row in the generator matrix includes the at least some parameters. In other words, the first device only needs to determine the N−K+1 parameters based on the random seed, and map the N−K+1 parameters to corresponding locations in each row of the matrix, to obtain the generator matrix, so as to reduce complexity of the generator matrix while ensuring randomness, and improve operating efficiency of the first device.

Further, any two rows in the generator matrix are different, to ensure that a code distance between random codes is large enough and error correction performance is better.

In a possible design solution, the parameter of the first device may include one or more of the following: an identifier of the first device or an address of the first device.

In a possible design solution, the parameter of the second device may include one or more of the following: an identifier of the second device or an address of the second device.

It can be learned that device identifiers of different devices are usually different, to ensure that the different devices have different random seeds and different random codes, so as to avoid reducing flexibility and diversity of channel encoding and reducing security because the different devices perform channel encoding by using a same random code.

In a possible design solution, the channel encoding parameter may include one or more of the following items for channel encoding: a length of the first data, an encoding length, or an encoding rate. The encoding length and the encoding rate usually depend on a quantity of resources of the first device, for example, a quantity of available frequency-domain resources such as a quantity of resource elements, or a quantity of available time-domain resources such as a quantity of symbols. In other words, the first device may determine a matched channel encoding parameter based on a quantity of currently available resources. For example, the encoding length for channel encoding matches a quantity of currently available time-domain resources, so that coded data can match a tolerance capability of the time-frequency resources, and rate matching does not need to be performed subsequently. Therefore, a coding chain can be simplified, and encoding efficiency can be improved. In addition, lengths of different data are usually different, to ensure that the different data has different random seeds and different random codes, so as to avoid reducing flexibility and diversity of channel encoding and reducing security because a same random code is used for channel encoding for the different data.

Optionally, the encoding length for the channel encoding is greater than or equal to a first length threshold, or the encoding length for the channel encoding is less than or equal to a second length threshold, where the first length threshold is less than the second length threshold. It may be understood that, if the encoding length for the channel encoding is excessively short, randomness of the random code is insufficient. Consequently, the code distance is excessively small, and an error correction capability of the random code is affected. If the encoding length for the channel encoding is excessively long, the random code is excessively complex, and decoding is difficult. Therefore, a moderate encoding length may be used, for example, an encoding length that is greater than the first length threshold and less than the second length threshold, so that the random code can balance characteristics of a large code distance and low decoding difficulty.

Optionally, the encoding rate for channel encoding is greater than or equal to a first rate threshold, or the encoding rate for channel encoding is less than or equal to a second rate threshold, where the first rate threshold is less than the second rate threshold. It may be understood that when the encoding rate for channel encoding is large, for example, greater than or equal to the first rate threshold, or is small, for example, less than or equal to the second rate threshold, decoding difficulty for channel encoding is low, and decoding accuracy can be ensured.

In a possible design solution, before the first device performs channel encoding on the first data based on the generator matrix to obtain the second data, the method according to the first aspect may further include: The first device receives configuration information from a third device. The configuration information includes one or more of the following: the generator matrix, the channel encoding parameter, the parameter of the first device, or the parameter of the second device. In other words, the generator matrix used for channel encoding or a parameter for determining the generator matrix may be directly configured by the third device, and does not need to be determined by the first device. This can improve encoding efficiency of the first device.

According to a second aspect, a communication method is provided. The method includes: A second device receives second data from a first device, and decodes the second data based on a generator matrix to obtain first data. At least some parameters in the generator matrix are determined based on a random seed, and the random seed is determined based on one or more of the following: a channel encoding parameter, a parameter of the first device, or a parameter of the second device.

In a possible design solution, the at least some parameters in the generator matrix are determined based on the random seed and a neural network.

In a possible design solution, the following relationship exists between the random seed and the parameter of the first device, the channel encoding parameter, and the parameter of the second device: seed=G[ƒ₁(x), ƒ₂(y), ƒ₃(z)], where seed is the random seed, x is the parameter of the first device, y is the parameter of the second device, z is the channel encoding parameter, G is a first function, ƒ₁ is a second function, ƒ₂ is a third function, and ƒ₃ is a fourth function.

In a possible design solution, the at least some parameters are determined by processing the random seed according to one or more of the following algorithms: a square number algorithm or a chaos algorithm.

In a possible design solution, the generator matrix is a K*N matrix, K and N are positive integers, K is less than N, and a quantity of the at least some parameters is any one of K*(N−K), K*N, or N−K+1.

Optionally, the quantity of the at least some parameters is K*N. Alternatively, optionally, the quantity of the at least some parameters is K*(N−K), and K² parameters in the K*N parameters of the generator matrix other than the at least some parameters form an identity matrix. Alternatively, optionally, the quantity of the at least some parameters is N−K+1, and each row in the generator matrix includes the at least some parameters.

Further, any two rows in the generator matrix are different.

In a possible design solution, the parameter of the first device may include one or more of the following: an identifier of the first device or an address of the first device.

In a possible design solution, the parameter of the second device may include one or more of the following: an identifier of the second device or an address of the second device.

In a possible design solution, the channel encoding parameter may include one or more of the following items for channel encoding: a length of the first data, an encoding length, or an encoding rate.

Optionally, the encoding length for the channel encoding is greater than or equal to a first length threshold, or the encoding length for the channel encoding is less than or equal to a second length threshold, where the first length threshold is less than the second length threshold.

Optionally, the encoding rate for channel encoding is greater than or equal to a first rate threshold, or the encoding rate for channel encoding is less than or equal to a second rate threshold, where the first rate threshold is less than the second rate threshold.

In a possible design solution, before the second device decodes the second data based on the generator matrix to obtain the first data, the method according to the second aspect may further include: The second device receives configuration information from a third device. The configuration information includes one or more of the following: the generator matrix, the channel encoding parameter, the parameter of the first device, or the parameter of the second device. In other words, the generator matrix used for channel encoding or a parameter for determining the generator matrix may be directly configured by the third device, and does not need to be determined by the second device. This can improve decoding efficiency of the second device.

In addition, for technical effect of the method according to the second aspect, refer to the technical effect of the method according to the first aspect. Details are not described herein again.

According to a third aspect, a communication method is provided. The method includes: A first device performs channel encoding on first data based on a generator matrix to obtain second data, and sends the second data to a second device. The generator matrix is determined based on one or more of the following: a channel encoding parameter, a parameter of the first device, or a parameter of the second device.

In a possible design solution, at least some parameters in the generator matrix are determined based on a random seed, and the random seed is determined based on one or more of the following: the channel encoding parameter, the parameter of the first device, or the parameter of the second device.

In a possible design solution, the at least some parameters in the generator matrix are determined based on the random seed and a neural network.

In a possible design solution, the following relationship exists between the random seed and the parameter of the first device, the channel encoding parameter, and the parameter of the second device: seed=G[ƒ₁(x), ƒ₂(y), ƒ₃(z)], where seed is the random seed, x is the parameter of the first device, y is the parameter of the second device, z is the channel encoding parameter, G is a first function, ƒ₁ is a second function, ƒ₂ is a third function, and ƒ₃ is a fourth function.

In a possible design solution, the at least some parameters are determined by processing the random seed according to one or more of the following algorithms: a square number algorithm or a chaos algorithm.

In a possible design solution, the generator matrix is a K*N matrix, K and N are positive integers, K is less than N, and a quantity of the at least some parameters is any one of K*(N−K), K*N, or N−K+1.

Optionally, the quantity of the at least some parameters is K*N. Alternatively, optionally, the quantity of the at least some parameters is K*(N−K), and K² parameters in the K*N parameters of the generator matrix other than the at least some parameters form an identity matrix. Alternatively, optionally, the quantity of the at least some parameters is N−K+1, and each row in the generator matrix includes the at least some parameters.

Further, any two rows in the generator matrix are different.

In a possible design solution, the parameter of the first device may include one or more of the following: an identifier of the first device or an address of the first device.

In a possible design solution, the parameter of the second device may include one or more of the following: an identifier of the second device or an address of the second device.

In a possible design solution, the channel encoding parameter may include one or more of the following items for channel encoding: a length of the first data, an encoding length, or an encoding rate.

Optionally, the encoding length for the channel encoding is greater than or equal to a first length threshold, or the encoding length for the channel encoding is less than or equal to a second length threshold, where the first length threshold is less than the second length threshold.

Optionally, the encoding rate for channel encoding is greater than or equal to a first rate threshold, or the encoding rate for channel encoding is less than or equal to a second rate threshold, where the first rate threshold is less than the second rate threshold.

In a possible design solution, before the first device performs channel encoding on the first data based on the generator matrix to obtain the second data, the method according to the third aspect may further include: The first device receives configuration information from a third device. The configuration information includes one or more of the following: the generator matrix, the channel encoding parameter, the parameter of the first device, or the parameter of the second device.

In addition, for technical effect of the method according to the third aspect, refer to the technical effect of the method according to the first aspect. Details are not described herein again.

According to a fourth aspect, a communication method is provided. The method includes: A second device receives second data from a first device, and decodes the second data based on a generator matrix to obtain first data. The generator matrix is determined based on one or more of the following: a channel encoding parameter, a parameter of the first device, or a parameter of the second device.

In a possible design solution, at least some parameters in the generator matrix are determined based on a random seed, and the random seed is determined based on one or more of the following: the channel encoding parameter, the parameter of the first device, or the parameter of the second device.

In a possible design solution, the at least some parameters in the generator matrix are determined based on the random seed and a neural network.

In a possible design solution, the following relationship exists between the random seed and the parameter of the first device, the channel encoding parameter, and the parameter of the second device: seed=G[ƒ₁(x), ƒ₂(y), ƒ₃ (z)], where seed is the random seed, x is the parameter of the first device, y is the parameter of the second device, z is the channel encoding parameter, G is a first function, ƒ₁ is a second function, ƒ₂ is a third function, and ƒ₃ is a fourth function.

In a possible design solution, the at least some parameters are determined by processing the random seed according to one or more of the following algorithms: a square number algorithm or a chaos algorithm.

In a possible design solution, the generator matrix is a K*N matrix, K and N are positive integers, K is less than N, and a quantity of the at least some parameters is any one of K*(N−K), K*N, or N−K+1.

Optionally, the quantity of the at least some parameters is K*N. Alternatively, optionally, the quantity of the at least some parameters is K*(N−K), and K² parameters in the K*N parameters of the generator matrix other than the at least some parameters form an identity matrix. Alternatively, optionally, the quantity of the at least some parameters is N−K+1, and each row in the generator matrix includes the at least some parameters.

Further, any two rows in the generator matrix are different.

In a possible design solution, the parameter of the first device may include one or more of the following: an identifier of the first device or an address of the first device.

In a possible design solution, the parameter of the second device may include one or more of the following: an identifier of the second device or an address of the second device.

In a possible design solution, the channel encoding parameter may include one or more of the following items for channel encoding: a length of the first data, an encoding length, or an encoding rate.

Optionally, the encoding length for the channel encoding is greater than or equal to a first length threshold, or the encoding length for the channel encoding is less than or equal to a second length threshold, where the first length threshold is less than the second length threshold.

Optionally, the encoding rate for channel encoding is greater than or equal to a first rate threshold, or the encoding rate for channel encoding is less than or equal to a second rate threshold, where the first rate threshold is less than the second rate threshold.

In a possible design solution, before the second device decodes the second data based on the generator matrix to obtain the first data, the method according to the fourth aspect may further include: The second device receives configuration information from a third device. The configuration information includes one or more of the following: the generator matrix, the channel encoding parameter, the parameter of the first device, or the parameter of the second device. In addition, for technical effect of the method according to the fourth aspect, refer to the technical effect of the method according to the first aspect. Details are not described herein again.

According to a fifth aspect, a communication apparatus is provided. The apparatus includes a transceiver module and a processing module. The processing module is configured to perform channel encoding on first data based on a generator matrix to obtain second data, and the transceiver module is configured to send the second data to a second device. At least some parameters in the generator matrix are determined based on a random seed, and the random seed is determined based on one or more of the following: a channel encoding parameter, a parameter of the communication apparatus according to the fifth aspect, or a parameter of the second device.

In a possible design solution, the at least some parameters in the generator matrix are determined based on the random seed and a neural network.

In a possible design solution, the following relationship exists between the random seed and the channel encoding parameter, the parameter of the communication apparatus according to the fifth aspect, and the parameter of the second device: seed=G[ƒ₁(x), ƒ₂(y), ƒ₃(z)], where seed is the random seed, x is the parameter of the communication apparatus according to the fifth aspect, y is the parameter of the second device, z is the channel encoding parameter, G is a first function, ƒ₁ is a second function, ƒ₂ is a third function, and ƒ₃ is a fourth function.

In a possible design solution, the at least some parameters are determined by processing the random seed according to one or more of the following algorithms: a square number algorithm or a chaos algorithm.

In a possible design solution, the generator matrix is a K*N matrix, K and N are positive integers, K is less than N, and a quantity of the at least some parameters is any one of K*(N−K), K*N, or N−K+1.

Optionally, the quantity of the at least some parameters is K*N. Alternatively, optionally, the quantity of the at least some parameters is K*(N−K), and K² parameters in the K*N parameters of the generator matrix other than the at least some parameters form an identity matrix. Alternatively, optionally, the quantity of the at least some parameters is N−K+1, and each row in the generator matrix includes the at least some parameters.

Further, any two rows in the generator matrix are different.

In a possible design solution, the parameter of the communication apparatus according to the fifth aspect may include one or more of the following: an identifier of the communication apparatus according to the fifth aspect or an address of the communication apparatus according to the fifth aspect.

In a possible design solution, the parameter of the second device may include one or more of the following: an identifier of the second device or an address of the second device.

In a possible design solution, the channel encoding parameter may include one or more of the following items for channel encoding: a length of the first data, an encoding length, or an encoding rate.

Optionally, the encoding length for the channel encoding is greater than or equal to a first length threshold, or the encoding length for the channel encoding is less than or equal to a second length threshold, where the first length threshold is less than the second length threshold.

Optionally, the encoding rate for channel encoding is greater than or equal to a first rate threshold, or the encoding rate for channel encoding is less than or equal to a second rate threshold, where the first rate threshold is less than the second rate threshold.

In a possible design solution, the transceiver module is further configured to: before the processing module performs channel encoding on the first data based on the generator matrix to obtain the second data, receive configuration information from a third device. The configuration information includes one or more of the following: the generator matrix, the channel encoding parameter, the parameter of the communication apparatus according to the fifth aspect, or the parameter of the second device.

Optionally, the transceiver module may alternatively include a sending module and a receiving module. The sending module is configured to implement a sending function of the apparatus according to the fifth aspect, and the receiving module is configured to implement a receiving function of the apparatus according to the fifth aspect.

Optionally, the apparatus according to the fifth aspect may further include a storage module, and the storage module stores a program or instructions. When the processing module executes the program or the instructions, the apparatus may be enabled to perform the method according to the first aspect.

It should be noted that the apparatus according to the fifth aspect may be a terminal or a network device, or may be a chip (system) or another component or assembly that may be disposed in a terminal or a network device, or may be an apparatus that includes a terminal or a network device. This is not limited in this application.

In addition, for technical effect of the apparatus according to the fifth aspect, refer to the technical effect of the method according to the first aspect. Details are not described herein again.

According to a sixth aspect, a communication apparatus is provided. The apparatus includes: a transceiver module and a processing module. The transceiver module is configured to receive second data from a first device, and the processing module is configured to decode the second data based on a generator matrix to obtain first data. At least some parameters in the generator matrix are determined based on a random seed, and the random seed is determined based on one or more of the following: a channel encoding parameter, a parameter of the first device, or a parameter of communication apparatus according to the sixth aspect.

In a possible design solution, the at least some parameters in the generator matrix are determined based on the random seed and a neural network.

In a possible design solution, the following relationship exists between the random seed and the channel encoding parameter, the parameter of the first device, and the parameter of the communication apparatus according to the sixth aspect: seed=G[ƒ₁(x), ƒ₂(y), ƒ₃(z)], where seed is the random seed, x is the parameter of the first device, y is the parameter of the communication apparatus according to the sixth aspect, z is the channel encoding parameter, G is a first function, ƒ₁ is a second function, ƒ₂ is a third function, and ƒ₃ is a fourth function.

In a possible design solution, the at least some parameters are determined by processing the random seed according to one or more of the following algorithms: a square number algorithm or a chaos algorithm.

In a possible design solution, the generator matrix is a K*N matrix, K and N are positive integers, K is less than N, and a quantity of the at least some parameters is any one of K*(N−K), K*N, or N−K+1.

Optionally, the quantity of the at least some parameters is K*N. Alternatively, optionally, the quantity of the at least some parameters is K*(N−K), and K² parameters in the K*N parameters of the generator matrix other than the at least some parameters form an identity matrix. Alternatively, optionally, the quantity of the at least some parameters is N−K+1, and each row in the generator matrix includes the at least some parameters.

Further, any two rows in the generator matrix are different.

In a possible design solution, the parameter of the first device may include one or more of the following: an identifier of the first device or an address of the first device.

In a possible design solution, the parameter of communication apparatus according to the sixth aspect may include one or more of the following: an identifier of the communication apparatus according to the sixth aspect or an address of the communication apparatus according to the sixth aspect.

In a possible design solution, the channel encoding parameter may include one or more of the following items for channel encoding: a length of the first data, an encoding length, or an encoding rate.

Optionally, the encoding length for the channel encoding is greater than or equal to a first length threshold, or the encoding length for the channel encoding is less than or equal to a second length threshold, where the first length threshold is less than the second length threshold.

Optionally, the encoding rate for channel encoding is greater than or equal to a first rate threshold, or the encoding rate for channel encoding is less than or equal to a second rate threshold, where the first rate threshold is less than the second rate threshold.

In a possible design solution, the transceiver module is further configured to: before the processing module decodes the second data based on the generator matrix to obtain the first data, receive configuration information from a third device. The configuration information includes one or more of the following: the generator matrix, the channel encoding parameter, the parameter of the first device, or the parameter of the communication apparatus according to the sixth aspect.

Optionally, the transceiver module may alternatively include a sending module and a receiving module. The sending module is configured to implement a sending function of the apparatus according to the sixth aspect, and the receiving module is configured to implement a receiving function of the apparatus according to the sixth aspect.

Optionally, the apparatus according to the sixth aspect may further include a storage module, and the storage module stores a program or instructions. When the processing module executes the program or the instructions, the apparatus may be enabled to perform the method according to the second aspect.

It should be noted that the apparatus according to the sixth aspect may be a terminal or a network device, or may be a chip (system) or another component or assembly that may be disposed in a terminal or a network device, or may be an apparatus that includes a terminal or a network device. This is not limited in this application.

In addition, for technical effect of the apparatus according to the sixth aspect, refer to the technical effect of the method according to the first aspect. Details are not described herein again.

According to a seventh aspect, a communication apparatus is provided. The apparatus includes: a transceiver module and a processing module. The processing module is configured to perform channel encoding on first data based on a generator matrix to obtain second data, and the transceiver module is configured to send the second data to a second device. The generator matrix is determined based on one or more of the following: a channel encoding parameter, a parameter of the communication apparatus according to the seventh aspect, or a parameter of the second device.

In a possible design solution, at least some parameters in the generator matrix are determined based on a random seed, and the random seed is determined based on one or more of the following: the channel encoding parameter, the parameter of the communication apparatus according to the seventh aspect, or the parameter of the second device.

In a possible design solution, the at least some parameters in the generator matrix are determined based on the random seed and a neural network.

In a possible design solution, the following relationship exists between the random seed and the channel encoding parameter, the parameter of the communication apparatus according to the seventh aspect, and the parameter of the second device: seed=G[ƒ₁(x), ƒ₂(y), ƒ₃(z)], where seed is the random seed, x is the parameter of the communication apparatus according to the seventh aspect, y is the parameter of the second device, z is the channel encoding parameter, G is a first function, ƒ₁ is a second function, ƒ₂ is a third function, and ƒ₃ is a fourth function.

In a possible design solution, the at least some parameters are determined by processing the random seed according to one or more of the following algorithms: a square number algorithm or a chaos algorithm.

In a possible design solution, the generator matrix is a K*N matrix, K and N are positive integers, K is less than N, and a quantity of the at least some parameters is any one of K*(N−K), K*N, or N−K+1.

Optionally, the quantity of the at least some parameters is K*N. Alternatively, optionally, the quantity of the at least some parameters is K*(N−K), and K² parameters in the K*N parameters of the generator matrix other than the at least some parameters form an identity matrix. Alternatively, optionally, the quantity of the at least some parameters is N−K+1, and each row in the generator matrix includes the at least some parameters.

Further, any two rows in the generator matrix are different.

In a possible design solution, the parameter of the communication apparatus according to the seventh aspect may include one or more of the following: an identifier of the communication apparatus according to the seventh aspect or an address of the communication apparatus according to the seventh aspect.

In a possible design solution, the parameter of the second device may include one or more of the following: an identifier of the second device or an address of the second device.

In a possible design solution, the channel encoding parameter may include one or more of the following items for channel encoding: a length of the first data, an encoding length, or an encoding rate.

Optionally, the encoding length for the channel encoding is greater than or equal to a first length threshold, or the encoding length for the channel encoding is less than or equal to a second length threshold, where the first length threshold is less than the second length threshold.

Optionally, the encoding rate for channel encoding is greater than or equal to a first rate threshold, or the encoding rate for channel encoding is less than or equal to a second rate threshold, where the first rate threshold is less than the second rate threshold.

In a possible design solution, the transceiver module is further configured to: before the processing module performs channel encoding on the first data based on the generator matrix to obtain the second data, receive configuration information from a third device. The configuration information includes one or more of the following: the generator matrix, the channel encoding parameter, the parameter of the communication apparatus according to the seventh aspect, or the parameter of the second device.

Optionally, the transceiver module may alternatively include a sending module and a receiving module. The sending module is configured to implement a sending function of the apparatus according to the seventh aspect, and the receiving module is configured to implement a receiving function of the apparatus according to the seventh aspect.

Optionally, the apparatus according to the seventh aspect may further include a storage module, and the storage module stores a program or instructions. When the processing module executes the program or the instructions, the apparatus may be enabled to perform the method according to the third aspect.

It should be noted that the apparatus according to the seventh aspect may be a terminal or a network device, or may be a chip (system) or another component or assembly that may be disposed in a terminal or a network device, or may be an apparatus that includes a terminal or a network device. This is not limited in this application.

In addition, for technical effect of the apparatus according to the seventh aspect, refer to the technical effect of the method according to the first aspect. Details are not described herein again.

According to an eighth aspect, a communication apparatus is provided. The apparatus includes: a transceiver module and a processing module. The transceiver module is configured to receive second data from a first device, and the processing module is configured to decode the second data based on a generator matrix to obtain first data. The generator matrix is determined based on one or more of the following: a channel encoding parameter, a parameter of the first device, or a parameter of the communication apparatus according to the eighth aspect.

In a possible design solution, at least some parameters in the generator matrix are determined based on a random seed, and the random seed is determined based on one or more of the following: the channel encoding parameter, the parameter of the first device, or the parameter of communication apparatus according to the eighth aspect.

In a possible design solution, the at least some parameters in the generator matrix are determined based on the random seed and a neural network.

In a possible design solution, the following relationship exists between the random seed and the channel encoding parameter, the parameter of the first device, and the parameter of the communication apparatus according to the eighth aspect: seed=G[ƒ₁(x), ƒ₂(y), ƒ₃(z)], where seed is the random seed, x is the parameter of the first device, y is the parameter of the communication apparatus according to the eighth aspect, z is the channel encoding parameter, G is a first function, ƒ₁ is a second function, ƒ₂ is a third function, and ƒ₃ is a fourth function.

In a possible design solution, the at least some parameters are determined by processing the random seed according to one or more of the following algorithms: a square number algorithm or a chaos algorithm.

In a possible design solution, the generator matrix is a K*N matrix, K and N are positive integers, K is less than N, and a quantity of the at least some parameters is any one of K*(N−K), K*N, or N−K+1.

Optionally, the quantity of the at least some parameters is K*N. Alternatively, optionally, the quantity of the at least some parameters is K*(N−K), and K² parameters in the K*N parameters of the generator matrix other than the at least some parameters form an identity matrix. Alternatively, optionally, the quantity of the at least some parameters is N−K+1, and each row in the generator matrix includes the at least some parameters.

Further, any two rows in the generator matrix are different.

In a possible design solution, the parameter of the first device may include one or more of the following: an identifier of the first device or an address of the first device.

In a possible design solution, the communication apparatus according to the eighth aspect may include one or more of the following: an identifier of the communication apparatus according to the eighth aspect or an address of the communication apparatus according to the eighth aspect.

In a possible design solution, the channel encoding parameter may include one or more of the following items for channel encoding: a length of the first data, an encoding length, or an encoding rate.

Optionally, the encoding length for the channel encoding is greater than or equal to a first length threshold, or the encoding length for the channel encoding is less than or equal to a second length threshold, where the first length threshold is less than the second length threshold.

Optionally, the encoding rate for channel encoding is greater than or equal to a first rate threshold, or the encoding rate for channel encoding is less than or equal to a second rate threshold, where the first rate threshold is less than the second rate threshold.

In a possible design solution, the transceiver module is further configured to: before the processing module decodes the second data based on the generator matrix to obtain the first data, receive configuration information from a third device. The configuration information includes one or more of the following: the generator matrix, the channel encoding parameter, the parameter of the first device, or the parameter of the communication apparatus according to the eighth aspect.

Optionally, the transceiver module may alternatively include a sending module and a receiving module. The sending module is configured to implement a sending function of the apparatus according to the eighth aspect, and the receiving module is configured to implement a receiving function of the apparatus according to the eighth aspect.

Optionally, the apparatus according to the eighth aspect may further include a storage module, and the storage module stores a program or instructions. When the processing module executes the program or the instructions, the apparatus may be enabled to perform the method according to the fourth aspect.

It should be noted that the apparatus according to the eighth aspect may be a terminal or a network device, or may be a chip (system) or another component or assembly that may be disposed in a terminal or a network device, or may be an apparatus that includes a terminal or a network device. This is not limited in this application.

In addition, for technical effect of the apparatus according to the eighth aspect, refer to the technical effect of the method according to the first aspect. Details are not described herein again.

According to a ninth aspect, a communication apparatus is provided. The apparatus includes a processor. The processor is configured to perform the method according to any one of the first aspect to the fourth aspect.

In a possible design solution, the apparatus according to the ninth aspect may further include a transceiver. The transceiver may be a transceiver circuit or an interface circuit. The transceiver may be used by the apparatus to communicate with another apparatus.

In a possible design solution, the apparatus according to the ninth aspect may further include a memory. The memory and the processor may be integrated together, or may be disposed separately. The memory may be configured to store a computer program and/or data related to the method according to any one of the first aspect to the fourth aspect.

In this application, the apparatus according to the ninth aspect may be a terminal or a network device, or may be a chip (system) or another component or assembly that may be disposed in a terminal or a network device, or may be an apparatus that includes a terminal or a network device.

In addition, for technical effect of the apparatus according to the ninth aspect, refer to the technical effect of the method according to any one of the first aspect to the fourth aspect. Details are not described herein again.

According to a tenth aspect, a communication apparatus is provided. The apparatus includes a processor and a memory. The memory is configured to store computer instructions.

When the processor executes the instructions, the apparatus performs the method according to any one of the first aspect to the fourth aspect.

In a possible design solution, the apparatus according to the tenth aspect may further include a transceiver. The transceiver may be a transceiver circuit or an interface circuit. The transceiver may be used by the apparatus to communicate with another apparatus.

In this application, the apparatus according to the tenth aspect may be a terminal or a network device, or may be a chip (system) or another component or assembly that may be disposed in a terminal or a network device, or may be an apparatus that includes a terminal or a network device.

In addition, for technical effect of the apparatus according to the tenth aspect, refer to the technical effect of the method according to any one of the first aspect to the fourth aspect. Details are not described herein again.

According to an eleventh aspect, a communication apparatus is provided. The apparatus includes a logic circuit and an input/output interface. The input/output interface is configured to receive code instructions and transmit the code instructions to the logic circuit, and the logic circuit is configured to run the code instructions to perform the method according to any one of the first aspect to the fourth aspect.

In this application, the apparatus according to the eleventh aspect may be a terminal or a network device, or may be a chip (system) or another component or assembly that may be disposed in a terminal or a network device, or may be an apparatus that includes a terminal or a network device.

In addition, for technical effect of the apparatus according to the eleventh aspect, refer to the technical effect of the method according to any one of the first aspect to the fourth aspect. Details are not described herein again.

According to a twelfth aspect, a communication apparatus is provided. The apparatus includes a processor and a transceiver. The transceiver is configured to exchange information between the communication apparatus and another apparatus, and the processor executes program instructions to perform the method according to any one of the first aspect to the fourth aspect.

In a possible design solution, the apparatus according to the twelfth aspect may further include a memory. The memory and the processor may be integrated together, or may be disposed separately. The memory may be configured to store a computer program and/or data related to the method according to any one of the first aspect to the fourth aspect.

In this application, the apparatus according to the twelfth aspect may be a terminal or a network device, or may be a chip (system) or another component or assembly that may be disposed in a terminal or a network device, or may be an apparatus that includes a terminal or a network device.

In addition, for technical effect of the apparatus according to the twelfth aspect, refer to the technical effect of the method according to any one of the first aspect to the fourth aspect. Details are not described herein again.

According to a thirteenth aspect, a communication system is provided. The communication system includes one or more network devices, or one or more terminals. The terminal or the network device is configured to perform the method according to any one of the first aspect to the fourth aspect.

According to a fourteenth aspect, a computer-readable storage medium is provided, including computer programs or instructions. When the computer programs or instructions are run on a computer, the method according to any one of the first aspect to the fourth aspect is performed by the computer.

According to a fifteenth aspect, a computer program product is provided, including computer programs or instructions. When the computer programs or instructions are run on a computer, the method according to any one of the first aspect to the fourth aspect is performed by the computer.

### BRIEF DESCRIPTION OF DRAWINGS

FIG. 1 is a schematic flowchart of channel encoding;

FIG. 2 is a schematic diagram of an architecture of a communication system according to an embodiment of this application;

FIG. 3 is a schematic flowchart of a communication method according to an embodiment of this application;

FIG. 4 is a schematic diagram 1 of a structure of a communication apparatus according to an embodiment of this application;

FIG. 5 is a schematic diagram 2 of a structure of a communication apparatus according to an embodiment of this application; and

FIG. 6 is a schematic diagram 3 of a structure of a communication apparatus according to an embodiment of this application.

### DESCRIPTION OF EMBODIMENTS

The following describes technical terms in embodiments of this application.

### 1. Channel Coding

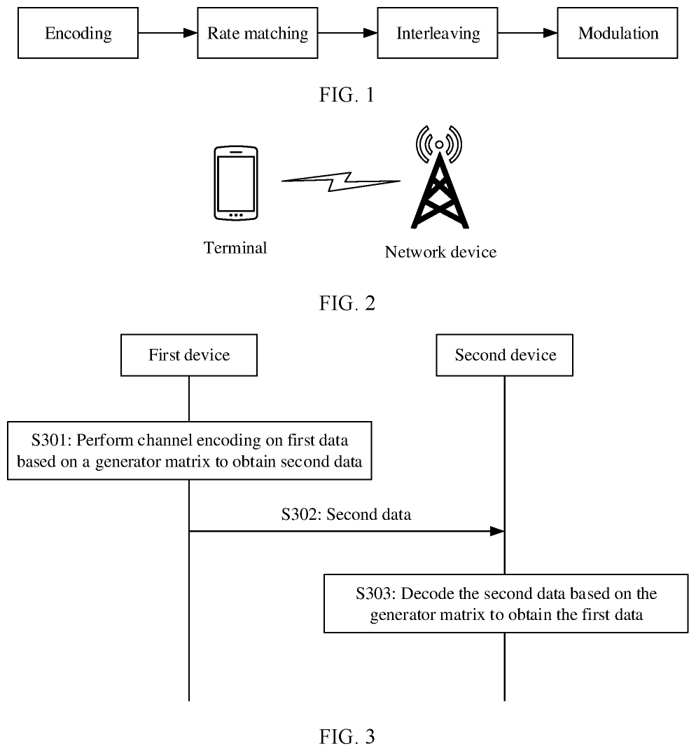

Channel coding is a key technology in the communication field, and is used to protect data during data transmission and restore data when data errors occur. Generally, a structural code is used for channel coding, for example, a polar code, an RM code, an LDPC code, or a BCH code. FIG. 1 is a schematic diagram of an encoding procedure of a structural code. As shown in FIG. 1, the encoding procedure of the structural code may include encoding, rate matching, interleaving, and modulation.

Encoding means that a transmit end performs channel encoding on original data by using the structural code, for example, a polar code or an RM code whose length of a mother code is 2^{m} bits, where m is a positive integer, for example, 64 bits, 128 bits, or 256 bits, or a BCH code whose length of a mother code is 2^{m}−1 bits, for example, 7 bits, 15 bits, or 31 bits, to obtain encoded data that may also be referred to as a code block.

Rate matching means that when time-frequency resources required for carrying the to-be-transmitted encoded data are inconsistent with current time-frequency resources, the transmit end performs bit retransmission or puncturing on the to-be-transmitted encoded data, to match a tolerance capability of the time-frequency resources, which is also referred to as matching a channel length requirement, so as to ensure that the to-be-transmitted encoded data can be carried by these time-frequency resources.

Interleaving means that the transmit end reorders a transmission order of the to-be-transmitted encoded data, to disrupt interference, for example, a burst bit error in a transmission process, and reduce impact of the interference on transmission quality.

Modulation means that the transmit end maps the encoded data disordered through interleaving to a corresponding carrier or subcarrier, to send the encoded data to a receive end by using the carrier or the subcarrier.

For the receive end, the receive end may demodulate the encoded data from the transmit end, and decode the demodulated data by using a decoding algorithm corresponding to the structural code, for example, a continuous deletion decoding algorithm, a belief propagation decoding algorithm, or a Berlekamp-Massey (BM) decoding algorithm, to restore the original data.

Therefore, it can be learned from the foregoing descriptions of the encoding and decoding procedures that a designed code structure is used for the structural code. For example, the length of the mother code of the polar code or the RM code can be only 2^{m} bits, and the length of the mother code of the BCH code can be only 2^{m}−1 bits. As a result, the structural code is not flexible and diversified. For example, the encoded data usually cannot adapt to the current time-frequency resources, and randomness is insufficient. In addition, rate matching and interleaving need to be performed on the encoded data. As a result, a coding chain is complex and encoding efficiency is low. In addition, although the designed code structure can reduce decoding difficulty, it is easy to be directly deciphered. Therefore, security of the code structure is not high enough.

For the foregoing technical problem, embodiments of this application provide the following technical solutions:

The technical solutions provided in embodiments of this application may be applied to various communication systems, for example, a wireless fidelity (Wi-Fi) system, a vehicle-to-everything (V2X) communication system, a device-to-device (D2D) communication system, an internet of vehicles communication system, a 4th generation (4G) mobile communication system such as a long term evolution (LTE) system, a 5th generation (5G) mobile communication system such as a new radio (NR) system, and a future communication system such as a 6th generation (6G) mobile communication system.

All aspects, embodiments, or features are presented in this application by describing a system that may include a plurality of devices, components, modules, and the like. It should be appreciated and understood that, each system may include another device, component, module, and the like, and/or may not include all devices, components, modules, and the like discussed with reference to accompanying drawings. In addition, a combination of these solutions may be used.

In addition, in embodiments of this application, the word such as “example” or “for example” is used to represent giving an example, an illustration, or a description. Any embodiment or design scheme described as an “example” in this application should not be explained as being more preferred or having more advantages than another embodiment or design scheme. Exactly, the term “example” is used to present a concept in a specific manner.

In embodiments of this application, terms “information”, “signal”, “message”, “channel”, and “signaling” may sometimes be interchangeably used. It should be noted that meanings expressed by the terms are consistent when differences of the terms are not emphasized. The terms “of”, “relevant”, and “corresponding” may sometimes be interchangeably used. It should be noted that meanings expressed by the terms are consistent when differences of the terms are not emphasized.

A network architecture and a service scenario described in embodiments of this application are intended to describe the technical solutions in embodiments of this application more clearly, but do not constitute a limitation on the technical solutions provided in embodiments of this application. A person of ordinary skill in the art may know that with evolution of the network architecture and emergence of a new service scenario, the technical solutions provided in embodiments of this application are also applicable to a similar technical problem.

For ease of understanding of embodiments of this application, a communication system applicable to embodiments of this application is first described in detail by using a communication system shown in FIG. 2 as an example. For example, FIG. 2 is a schematic diagram of an architecture of the communication system to which a communication method provided in embodiments of this application is applicable.

As shown in FIG. 2, the communication system includes a terminal and a network device.

The terminal is a terminal that accesses the communication system and that has a wireless transceiver function, or a chip or a chip system that may be disposed in a terminal. The terminal may also be referred to as user equipment (UE), an access terminal, a subscriber unit, a subscriber station, a mobile station (MS), a remote station, a remote terminal, a mobile device, a user terminal, a wireless communication device, a user agent, or a user apparatus. The terminal in this embodiment of this application may be a mobile phone, a cellular phone, a smartphone, a tablet computer (Pad), a wireless data card, a personal digital assistant (PDA), a wireless modem a handset, a laptop computer, a machine type communication (MTC) terminal, a computer that has a wireless transceiver function, a virtual reality (VR) terminal, an augmented reality (AR) terminal, a wireless terminal in industrial control, a wireless terminal in self-driving a wireless terminal in telemedicine (remote medical), a wireless terminal in a smart grid, a wireless terminal in transportation safety, a wireless terminal in a smart city, a wireless terminal in a smart home, a vehicle-mounted terminal, an RSU that has a terminal function, or the like. Alternatively, the terminal in this application may be a vehicle-mounted module, a vehicle-mounted subassembly, a vehicle-mounted component, a vehicle-mounted chip, or a vehicle-mounted unit that is built in a vehicle as one or more components or units.

The network device is a device that is located on a network side of the communication system and has a wireless transceiver function, or a chip or a chip system that may be disposed in a device. The network device may include: a gNB in 5G such as an NR system, or one antenna panel or a group of antenna panels (including a plurality of antenna panels) of a base station in a 5G system. Alternatively, the network device may be a network node that forms a gNB, a transmission point (transmission and reception point, TRP, or TP), or a transmission measurement function (TMF), for example, a baseband unit (BBU), a central unit (CU), a distributed unit (DU), a road side unit (RSU) that has a base station function, or a wired access gateway. In addition, in a system that uses different radio access technologies, a name of a network device may vary, for example, a base transceiver station (BTS) in a global system for mobile communications (GSM) or a code division multiple access (CDMA) network, an NB (NodeB) in wideband code division multiple access (WCDMA), or an eNB or eNodeB (evolved NodeB) in long term evolution (LTE). Alternatively, the network device may be a radio controller in a cloud radio access network (CRAN) scenario. In addition, the network device may alternatively include an access point (AP) in a Wi-Fi system, a wireless relay node, a wireless backhaul node, macro base stations in various forms, a micro base station (also referred to as a small cell), a relay station, an access point, a wearable device, a vehicle-mounted device, or the like.

The following describes in detail the communication method provided in embodiments of this application with reference to FIG. 3.

For example, FIG. 3 is a schematic flowchart 1 of the communication method provided in embodiments of this application. The communication method is applicable to communication between a terminal (a first device) and a terminal (a second device) in the communication system shown in FIG. 2, communication between a terminal and a network device (the terminal is a first device, and the network device is a second device, or the terminal is a second device, and the network device is a first device), or communication between a network device (a first device) and a network device (a second device). As shown in FIG. 3, the communication method includes S301, S302, and S303.

S301: The first device performs channel encoding on first data based on a generator matrix to obtain second data.

The generator matrix is determined based on one or more of the following: a channel encoding parameter, a parameter of the first device, or a parameter of the second device. In an implementation, at least some parameters in the generator matrix are determined based on a random seed, and the at least some parameters may also be considered as random codes. The random seed may be a true random number (seed) that is used as an initial condition to iteratively generate another random number, and is determined based on one or more of the following: the channel encoding parameter, the parameter of the first device, or the parameter of the second device.

The channel encoding parameter may include one or more of the following items for channel encoding: a length of the first data, for example, a bit sequence length of the first data; an encoding length, namely, a bit sequence length of a code block; or an encoding rate. Alternatively, the channel encoding parameter may include any other possible parameter for channel encoding, for example, a modulation order or a quantity of resource elements. This is not limited in this application. The encoding length and the encoding rate usually depend on a quantity of resources of the first device, for example, a quantity of available frequency-domain resources such as the quantity of resource elements (REs), or a quantity of available time-domain resources such as a quantity of symbols. In other words, the first device may determine a matched channel encoding parameter based on a quantity of currently available resources. For example, the encoding length for channel encoding matches a quantity of currently available time-domain resources, so that coded data can match a tolerance capability of the time-frequency resources, and rate matching does not need to be performed subsequently. Therefore, a coding chain can be simplified, and encoding efficiency can be improved. In addition, lengths of different data are usually different, to ensure that the different data has different random seeds and different random codes, so as to avoid reducing flexibility and diversity of channel encoding and reducing security because a same random code is used for channel encoding for the different data.

The parameter of the first device may include one or more of the following: an identifier (ID) of the first device or an address of the first device. The identifier of the first device may be any possible identifier such as a device identifier, a network identifier, or a service identifier. The address of the first device may be an internet protocol (IP) address of the first device, for example, a source IP address, or any other possible address.

The parameter of the second device may include one or more of the following: an identifier of the second device or an address of the second device. The identifier of the second device may be any possible identifier such as a device identifier, a network identifier, or a service identifier. The address of the second device may be an IP address of the second device, for example, a destination IP address, or any other possible address.

A relationship may exist between the random seed and the channel encoding parameter, the parameter of the first device, and the parameter of the second device. In other words, the first device may calculate one or more of the channel encoding parameter, the parameter of the first device, and the parameter of the second device based on the relationship, to obtain the random seed. For example, an example of the relationship may be shown in the following formula 1:

seed=G[ƒ₁(x),ƒ₂(y),ƒ₃(z)] (1)

In the foregoing formula 1, seed is the random seed, x is the parameter of the first device, y is the parameter of the second device, and z is the channel encoding parameter. G is a first function, for example, may be a log function, or may be an exp function or a polynomial function. ƒ₁ is a second function, for example, may be a log function, or may be an exp function or a polynomial function. ƒ₂ is a third function, for example, may be a log function, or may be an exp function or a polynomial function. ƒ₃ is a fourth function, for example, may be a log function, or may be an exp function or a polynomial function. In other words, the random seed is obtained by performing a function operation on the channel encoding parameter, the parameter of the first device, and the parameter of the second device. This can improve randomness of the random seed, to further improve flexibility and diversity of channel encoding, and further improve security. It should be noted that the first device does not need to use one or more of the foregoing parameters to determine the random seed, and a value of the parameter in the foregoing function may be set to 0. For example, if the first device determines not to use the parameter of the first device to determine the random seed, a value of x in ƒ₁ (x) may be set to 0. For another example, if the first device determines not to use the parameter of the first device and the channel encoding parameter to determine the random seed, a value of x in ƒ₁ (x) may be set to 0, and a value of z in ƒ₃ (z) may be set to 0. In addition, the random seed determined by using the foregoing function may be a bit sequence, for example, 1110111011 or 1001100000. Alternatively, the random seed determined by using the foregoing function may be a specific value, for example, 24, 32, or 40. In this case, the specific value may be converted into a corresponding bit sequence, to be used when the generator matrix is subsequently determined.

The first device may process the random seed according to one or more of the following algorithms: a square number algorithm or a chaos algorithm, to determine the at least some parameters in the generator matrix. Alternatively, the at least some parameters may be determined by processing the random seed according to the one or more of the foregoing algorithms. This can improve randomness of the at least some parameters, thereby further improving flexibility and diversity of channel encoding, and further improving security. The following separately describes the square number algorithm and the chaos algorithm.

### (A) Square Number Algorithm

The first device may determine a parameter in the at least some parameters based on the random seed. For example, the first device may obtain multiple bits (denoted as a bit sequence 1) from the random seed, for example, obtain first multiple bits, middle multiple bits, or last multiple bits from the random seed. Each bit in the bit sequence 1 is used as one corresponding parameter in the at least some parameters. In this case, if the at least some parameters have been all determined, execution of a subsequent procedure is stopped. If not all of the at least some parameters are determined, the first device may continue to determine a remaining parameter in the at least some parameters based on the bit sequence 1. For example, the first device may process the bit sequence 1, for example, calculate a square of the bit sequence 1, or fill in the bit sequence 1, to obtain a bit sequence (denoted as a bit sequence 2) longer than the bit sequence 1. Multiple bits (denoted as a bit sequence 3) in the bit sequence 2, for example, first multiple bits, middle multiple bits, or last multiple bits from the bit sequence 2 are obtained. Each bit in the bit sequence 3 is used as a corresponding remaining parameter in the at least some parameters. In this case, if the at least some parameters are all determined, execution of the subsequent procedure is stopped. If the at least some parameters are still not all determined, the foregoing procedure is iteratively performed until the at least some parameters are all determined. The following uses an example for description.

For example, it is assumed that a quantity of parameters in the at least some parameters is 16, and the random seed is 1110111011. The first device may obtain a bit sequence 1110 by using the first four bits (or may be other locations) of 1110111011, and 1110 is used as corresponding four parameters in the at least some parameters. The first device calculates a square of 1110 to obtain a bit sequence 11000110. The first device may obtain a bit sequence 1100 by using the first four bits of 11000110, and 1100 is also used as corresponding four parameters in the at least some parameters. The first device calculates a square of 1100 to obtain a bit sequence 10010000. The first device may obtain a bit sequence 1001 by using the first four bits of 10010000, and 1001 is also used as corresponding four parameters in the at least some parameters. The first device calculates a square of 1001 to obtain a bit sequence 1010001. The first device may obtain a bit sequence 1010 by using the first four bits of 1010001, and 1010 is used as corresponding last four parameters in the at least some parameters. Heretofore, calculation ends, and the 16 parameters of the at least some parameters may be represented as 1110, 1100, 1001, and 1010, or may be represented as 1110110010011010.

It should be noted that, for the foregoing iterative calculation, the first device may obtain multiple bits from a same location or from different locations. For example, for each iteration, the first device selects first multiple bits, middle multiple bits, or last multiple bits. For another example, in first time of iterative calculation, the first device obtains first multiple bits. In second time of iterative calculation, the first device obtains middle multiple bits. In third time of iterative calculation, the first device obtains last multiple bits. This is not limited in this application.

### (B) Chaos Algorithm

The first device may normalize the random seed to obtain a random number (denoted as a random number 1), and perform a first chaotic operation based on the random number 1, to obtain a new random number (denoted as a random number 2). The chaotic operation may satisfy the following function relationships:

$${k}_{i + 1} = h ( g ( {h}^{- 1} ( {k}_{i} ) ) ) \qquad ( 2 )$$

$$g ( s ) = \{ \begin{matrix}2 * s & s ∈ [ 0 , 0.5 ] \\ 2 * ( 1 - s ) & s ∈ ( 0.5 , 1 ]\end{matrix} \qquad ( 3 )$$

$$h ( t ) = \{ \begin{matrix}{t}^{2} + t / 2 & t ∈ [ 0 , 0.5 ] \\ 1 - h ( 1 - t ) & t ∈ ( 0.5 , 1 ]\end{matrix} \qquad ( 4 )$$

In the foregoing formulae 2 to 4, kᵢ is an input parameter of an i^{th} chaos operation, where i is a positive integer, for example, the random number 1 input in the first chaos operation or the random number 2 input in a subsequent second chaos operation. kᵢ₊₁ is an output parameter of the i^{th} chaotic operation, for example, the random number 2 obtained in the first chaotic operation or a random number 3 obtained in the subsequent second chaotic operation. s is a calculation result of h⁻¹ (kᵢ) in the formula 2, and t is a calculation result of g(s) in the formula 3. The first device may map the random number 2 to an integer (denoted as an integer 1) of 1 or 0 by using a mapping operation, where the integer 1 is a first parameter in the at least some parameters. The mapping operation may satisfy the following function relationship:

$$B ( {k}_{i + 1} ) = \{ \begin{matrix}1 & {k}_{i + 1} ∈ [ 0 , 0.5 ] \\ 0 & {k}_{i + 1} ∈ ( 0.5 , 1 ]\end{matrix} \qquad ( 5 )$$

The first device performs the second chaotic operation based on the random number 2, to obtain a new random number (denoted as the random number 3). The first device may map the random number 3 to an integer (denoted as an integer 2) of 1 or 0 based on a value of the random number 3, where the integer 2 is a second parameter in the at least some parameters. In this case, if the at least some parameters have been all determined, execution of the subsequent procedure is stopped. If not all of the at least some parameters are determined, the first device may perform a third chaotic operation based on the random number 3, to obtain a new random number (denoted as a random number 4). The first device may map the random number 4 to an integer (denoted as an integer 3) of 1 or 0 based on a value of the random number 4, where the integer 3 is a third parameter in the at least some parameters. In this case, if the at least some parameters are all determined, execution of the subsequent procedure is stopped. If the at least some parameters are still not all determined, the foregoing procedure is iteratively performed until the at least some parameters are all determined.

For ease of understanding, the following uses an example for description.

For example, it is assumed that a quantity of parameters in the at least some parameters is 4, and the random seed is 10. The first device normalizes 10 to obtain a random number 3/4, and performs a first chaotic operation based on 3/4 to obtain a new random number 0.6631. The first device performs a mapping operation on 0.6631 to obtain a first parameter 0 in the at least some parameters. In addition, the first device performs a second chaotic operation based on 0.6631, to obtain a new random number 0.8262. The first device performs a mapping operation on 0.8262, to obtain a second parameter 0 in the at least some parameters. In addition, the first device performs a third chaotic operation based on 0.8262, to obtain a new random number 0.4590. The first device performs a mapping operation on 0.4590, to obtain a third parameter 1 in the at least some parameters. In addition, the first device performs a fourth chaotic operation based on 0.4590, to obtain a new random number 0.9690. Finally, the first device performs a mapping operation on 0.9690, to obtain a fourth parameter 0 in the at least some parameters. Heretofore, the at least some parameters are all determined, and are respectively 0 0 1 0.

It should be noted that the foregoing manner of generating the random seed is dynamically generating the random seed in a coding process. This manner is merely an example, and is not intended as a limitation. For example, the first device may pre-generate a plurality of random seeds, or a plurality of random seeds are pre-configured by a network higher layer, for example, a core network. In the coding process, the first device may select a corresponding random seed from the plurality of random seeds, for example, randomly select the corresponding random seed or select the corresponding random seed according to a preset rule.

The generator matrix may be a K*N matrix, K and N are positive integers, K is less than N, K may be a data length of the first data, and N may be the encoding length for channel encoding. On this basis, a quantity of the at least some parameters determined based on the random seed may be any one of the following: K*N, K*(N−K), or N−K+1. This is not limited. For example, the quantity of the at least some parameters may alternatively be any other possible value, for example, a value predefined in a protocol or a random value.

In a first possible design solution, the quantity of the at least some parameters is K*N, in other words, all parameters in the generator matrix are determined based on the random seed, to further improve randomness of the generator matrix, thereby further improving flexibility and diversity of channel encoding, and further improving security. After determining the K*N parameters, the first device may structure the K*N parameters according to a predefined rule, for example, according to a row order or a column order of the matrix, for example, map the K*N parameters to corresponding locations in the matrix, to obtain the generator matrix. In addition, any two rows in the generator matrix are different, to ensure that a code distance between random codes is large enough, and error correction performance is better. The following uses an example for description.

For example, it is assumed that the generator matrix is a 3*5 matrix, and the at least some parameters are 110110111000011, that is, there are 15 parameters in total.

Manner 11: The first device may map the 15 parameters to corresponding locations in the matrix according to a parameter order of the at least some parameters and the row order of the matrix. For example, the first device maps the first five parameters 11011 of 110110111000011 to corresponding locations in the first row of the matrix, the first device maps the middle five parameters 01110 of 110110111000011 to corresponding locations in the second row of the matrix, and the first device maps the last five parameters 00011 of 110110111000011 to corresponding locations in the third row of the matrix. In this way, an obtained generator matrix W₁ may be shown in the following formula 6:

$${W}_{1} = \{ \begin{matrix}1 & 1 & 0 & 1 & 1 \\ 0 & 1 & 1 & 1 & 0 \\ 0 & 0 & 0 & 1 & 1\end{matrix} \} \qquad ( 6 )$$

It should be noted that the foregoing mapping according to the parameter order and the row order is merely an example, and is not intended as a limitation. For example, the first device may alternatively perform disordered mapping according to the parameter order and/or the row order. For example, the first device maps the first five parameters 11011 to the corresponding locations in the third row of the matrix, maps the middle five parameters 01110 to the corresponding locations in the first row of the matrix, and maps the last five parameters 00011 to the corresponding locations in the second row of the matrix. Alternatively, the first device may map the 15 parameters to corresponding locations in the matrix according to any other possible rule, provided that any two rows in the generator matrix are different. This is not limited in this application.

Manner 12: The first device may map the 15 parameters to corresponding locations in the matrix according to a parameter order of the at least some parameters and the column order of the matrix. For example, the first device maps the first to third parameters 110 of 110110111000011 to corresponding locations in the first column of the matrix, the first device maps the fourth to sixth parameters 110 of 110110111000011 to corresponding locations in the second column of the matrix, the first device maps the seventh to ninth parameters 111 of 110110111000011 to corresponding locations in the third column of the matrix, the first device maps the tenth to twelfth parameters 000 of 110110111000011 to corresponding locations in the fourth column of the matrix, and the first device maps the thirteenth to fifteenth parameters 011 of 110110111000011 to corresponding locations in the fifth column of the matrix. In this way, an obtained generator matrix W₂ may be shown in the following formula 7:

$${W}_{2} = \{ \begin{matrix}1 & 1 & 1 & 0 & 0 \\ 1 & 1 & 1 & 0 & 1 \\ 0 & 0 & 1 & 0 & 1\end{matrix} \} \qquad ( 7 )$$

It should be noted that the foregoing mapping according to the parameter order and the column order is merely an example, and is not intended as a limitation. For example, the first device may alternatively perform disordered mapping according to the parameter order and/or the column order. For example, the first device maps the first to third parameters 110 to the corresponding locations in the third column of the matrix, maps the fourth to sixth parameters 110 to the corresponding locations in the fifth column of the matrix, maps the seventh to ninth parameters 111 to the corresponding locations in the first column of the matrix, maps the tenth to twelfth parameters 000 to the corresponding locations in the second column of the matrix, and maps the thirteenth to fifteenth parameters 011 to the corresponding locations in the fourth column of the matrix. Alternatively, the first device may map the 15 parameters to corresponding locations in the matrix according to any other possible rule, provided that any two rows in the generator matrix are different. This is not limited in this application.

In a second possible design solution, the quantity of the at least some parameters is K*(N−K), and K² parameters in the K*N parameters of the generator matrix other than the at least some parameters form an identity matrix, so that the generator matrix may be used for systematic code coding. In other words, after determining the K*(N−K) parameters, the first device may structure the K*(N−K) parameters according to a preset rule or a protocol-predefined rule, for example, according to a row order or a column order of the matrix. For example, the K*N parameters are mapped to corresponding locations in the matrix other than the identity matrix, to obtain the generator matrix, and any two rows in the generator matrix are different, to ensure that a code distance between random codes is large enough, and error correction performance is better. The following uses an example for description.

For example, it is assumed that the generator matrix is a 3*5 matrix, and the at least some parameters are 110001, that is, there are six parameters in total.

Manner 21: The first device may map the six parameters to corresponding locations in the matrix other than the identity matrix according to a parameter order of the at least some parameters and the row order of the matrix. For example, the first three columns in the matrix form an identity matrix. The first device maps the first two parameters 11 of 110001 to corresponding locations in the fourth column and the fifth column in the first row of the matrix, the first device maps the two middle parameters 00 of 110001 to corresponding locations in the fourth column and the fifth column in the second row of the matrix, and the first device maps the last two parameters 01 of 110001 to corresponding locations in the fourth column and the fifth column in the third row of the matrix. In this way, an obtained generator matrix W₃ may be shown in the following formula 8:

$${W}_{3} = \{ \begin{matrix}1 & 0 & 0 & 1 & 1 \\ 0 & 1 & 0 & 0 & 0 \\ 0 & 0 & 1 & 0 & 1\end{matrix} \} \qquad ( 8 )$$

It should be noted that the foregoing mapping according to the parameter order and the row order is merely an example, and is not intended as a limitation. For example, the first device may alternatively perform disordered mapping according to the parameter order and/or the row order. For example, the first device maps the first two parameters 11 to the corresponding locations in the fourth column and the fifth column in the third row of the matrix, maps the middle two parameters 00 to the corresponding locations in the fourth column and the fifth column in the first row of the matrix, and maps the last two parameters 01 to the corresponding locations in the fourth column and the fifth column in the second row of the matrix. Alternatively, the first device may map the six parameters to corresponding locations in the matrix according to any other possible rule, provided that any two rows in the generator matrix are different. This is not limited in this application.

Manner 22: The first device may map the six parameters to corresponding locations in the matrix other than the identity matrix according to a parameter order of the at least some parameters and the column order of the matrix. For example, the first three columns in the matrix form an identity matrix. The first device maps the first three parameters 110 of 110001 to corresponding locations in the fourth column of the matrix, and the first device maps the last three parameters 001 of 110001 to corresponding locations in the fifth column of the matrix. In this way, an obtained generator matrix W₄ may be shown in the following formula 9:

$${W}_{4} = \{ \begin{matrix}1 & 0 & 0 & 1 & 0 \\ 0 & 1 & 0 & 1 & 0 \\ 0 & 0 & 1 & 0 & 1\end{matrix} \} \qquad ( 9 )$$

It should be noted that the foregoing mapping according to the parameter order and the column order is merely an example, and is not intended as a limitation. For example, the first device may alternatively perform disordered mapping according to the parameter order and/or the column order. For example, the first device maps the first three parameters 110 to the corresponding locations in the fifth column of the matrix, and maps the last three parameters 001 to the corresponding locations in the fourth column of the matrix. Alternatively, the first device may map the six parameters to corresponding locations in the matrix according to any other possible rule, provided that any two rows in the generator matrix are different. This is not limited in this application.

In a third possible design solution, the quantity of the at least some parameters is N−K+1, and each row in the generator matrix includes the at least some parameters. In other words, the first device only needs to determine the N−K+1 parameters based on the random seed, and map the N−K+1 parameters to corresponding locations in each row of the matrix, to obtain the generator matrix, so as to reduce complexity of the generator matrix while ensuring randomness, and improve operating efficiency of the first device. The N−K+1 parameters may be mapped to different locations in each row, so that any two rows in the generator matrix are different, to ensure that a code distance between random codes is large enough, and error correction performance is better. The following uses an example for description.

For example, it is assumed that the generator matrix is a 3*5 matrix, and the at least some parameters are 101, that is, there are three parameters in total. The first device may sequentially map, from left to right, the at least some parameters to corresponding locations in each row in the matrix. For example, for the first row of the matrix, the first device may map the at least some parameters 101 to corresponding locations in the first column to the third column in the first row of the matrix. For the second row of the matrix, the first device may map the at least some parameters 101 to corresponding locations in the second column to the fourth column in the second row of the matrix. For the third row of the matrix, the first device may map the at least some parameters 101 to corresponding locations in the third column to the fifth column in the third row of the matrix. In addition, the first device may further set 0 (or may set 1) at a location that is not mapped in the matrix. In this way, an obtained generator matrix W₅ may be shown in the following formula 10:

$${W}_{5} = \{ \begin{matrix}1 & 0 & 1 & 0 & 0 \\ 0 & 1 & 0 & 1 & 0 \\ 0 & 0 & 1 & 0 & 1\end{matrix} \} \qquad ( 10 )$$

It should be noted that the mapping performed by the first device from left to right is merely an example, and is not intended as a limitation. For example, the first device may alternatively perform mapping from right to left or in any other possible order, as long as it is ensured that any two rows in the generator matrix are different. This is not limited in this application.

It should be further noted that the foregoing manner of determining the generator matrix is merely an example, and is not intended as a limitation. For example, the first device may further obtain the encoded generator matrix based on the random seed and a neural network, in other words, the at least some parameters in the generator matrix are determined based on the random seed and the neural network. The random seed is input into the neural network, and the generator matrix is obtained based on an output of the neural network. For example, the random seed is input into a deep neural network to obtain an output value of the neural network, first K*N bits or last K*N bits of the output value in a binary form are obtained, and the generator matrix is obtained based on the first K*N bits or last K*N bits. For another example, the random seed is input to a recurrent neural network (or a long-term and short-term memory network). The recurrent neural network obtains an output value each time, and binarizes the output value to obtain a random number. K*N steps are repeatedly performed to obtain K*N random numbers, and the generator matrix is obtained based on the K*N random numbers.

In addition, the foregoing manner of determining the generator matrix is dynamically determining the generator matrix in the coding process. This manner is merely an example, and is not intended as a limitation. For example, the first device may pre-generate a plurality of generator matrices, or a plurality of generator matrices may be pre-configured by the network higher layer, for example, the core network. In the coding process, the first device may select a corresponding generator matrix from the plurality of generator matrices, for example, randomly select the corresponding generator matrix or select the corresponding generator matrix according to a preset rule.

Further, after obtaining the K*N generator matrix, the first device may use the generator matrix to encode the first data whose data length is K, to obtain the second data with a data length N. Because the second data is obtained through encoding, the second data may also be referred to as encoded data.

S302: The first device sends the second data to the second device. Correspondingly, the second device receives the second data from the first device.

The first device may modulate the second data, map the second data to corresponding carriers or subcarriers, and send the carriers or subcarriers to the second device. Correspondingly, after receiving the carriers or subcarriers, the second device may demodulate the carriers or subcarriers to obtain the second data.

S303: The second device decodes the second data based on the generator matrix to obtain the first data.

The second device may decode the second data based on the generator matrix and according to a decoding algorithm. In this case, if the second device performs decoding correctly, the second device obtains the first data. However, if the second device performs decoding incorrectly, data different from the first data, for example, third data, is obtained. In addition, the generator matrix is the same as the generator matrix determined by the first device. In other words, the second device may determine the generator matrix that is the same as that determined by the first device. For specific implementation, refer to the related descriptions in S301. Details are not described again. The decoding algorithm may be a general-purpose decoding algorithm, for example, a maximum likelihood (ML) decoding algorithm or an ordered statistics decoding (OSD) algorithm, or may be a specific decoding algorithm, for example, a continuous deletion decoding algorithm, a belief propagation decoding algorithm, or a BM decoding algorithm. This is not limited in this application.

In conclusion, with reference to the method shown in FIG. 3, it can be learned that the random seed is randomly determined, for example, determined based on one or more of the parameter of the first device, the channel encoding parameter, and the parameter of the second device. Therefore, the at least some parameters determined based on the random seed are also random, and may be considered as random codes. In this way, performing channel encoding on the first data by using the random codes can improve flexibility and diversity of channel encoding, and improve communication performance and security.

Optionally, in a first application scenario of the foregoing embodiment, before S301, the foregoing method may further include: The first device receives configuration information from a third device.

The first device and the third device may be devices of a same type. For example, the first device is a target access network device, and the third device is an anchor access network device. Alternatively, the first device and the third device may be devices of different types. For example, the first device is a terminal, and the third device is an access network device. For another example, the first device is an access network device, and the third device is a core network element. This is not limited in this application. The configuration information may include one or more of the following: the generator matrix, the channel encoding parameter, the parameter of the first device, or the parameter of the second device. In other words, the generator matrix used for channel encoding or a parameter for determining the generator matrix may be directly configured by the third device, and does not need to be determined by the first device, to improve encoding efficiency.

Optionally, in a second application scenario of the foregoing embodiment, before S302, the foregoing method may further include: The second device receives configuration information from a third device.

The second device and the third device may be devices of a same type. For example, the second device is a target access network device, and the third device is an anchor access network device. Alternatively, the second device and the third device may be devices of different types. For example, the second device is a terminal, and the third device is an access network device. For another example, the second device is an access network device, and the third device is a core network element. This is not limited in this application. The configuration information may include one or more of the following: the generator matrix, the channel encoding parameter, the parameter of the first device, or the parameter of the second device. In other words, the generator matrix used for channel encoding or a parameter for determining the generator matrix may be directly configured by the third device, and does not need to be determined by the second device, to improve decoding efficiency.

In addition, with reference to the first application scenario and the second application scenario, it can be learned that, because the third device may separately configure the same configuration information for the first device and the second device, the first device and the second device can separately perform encoding and decoding by using the same generator matrix, to ensure accuracy of encoding and decoding.

Optionally, in a third application scenario of the foregoing embodiment, when the first device performs channel encoding on the first data based on the generator matrix, the encoding length for the channel encoding may be greater than or equal to a first length threshold, or the encoding length for the channel encoding may be less than or equal to a second length threshold, where the first length threshold is less than the second length threshold. For example, the first length threshold may be 16 or 32 bits, and the second length threshold may be 128 or 256 bits. It may be understood that, if the encoding length for the channel encoding is excessively short, randomness of the random code is insufficient. Consequently, the code distance is excessively small, and an error correction capability of the random code is affected. If the encoding length for the channel encoding is excessively long, the random code is excessively complex, and decoding is difficult. Therefore, a moderate encoding length may be used, for example, an encoding length that is greater than the first length threshold and less than the second length threshold, so that the random code can balance characteristics of a large code distance and low decoding difficulty. In addition, for data whose encoding length is short, for example, the encoding length is less than the first length threshold, or for data whose encoding length is long, for example, the encoding length is greater than the second length threshold, the first device may perform channel encoding on the data by using a structural code, to implement compatibility between the random code and the structural code. Based on this, a coding rule may be shown in the following Table 1:

TABLE 1

| Index | Encoding length | Coding rule |
|---|---|---|
| 0 | L < L1 | Structural code |
| 1 | L1 ≤ L ≤ L2 | Random code |
| 2 | L > L2 | Structural code |

L is the encoding length for channel encoding, L1 is the first length threshold, and L2 is the second length threshold.

Optionally, in a fourth application scenario of the foregoing embodiment, when the first device performs channel encoding on the first data based on the generator matrix, the encoding rate for channel encoding may be greater than or equal to a first rate threshold, or the encoding rate for channel encoding may be less than or equal to a second rate threshold, where the first rate threshold is less than the second rate threshold. For example, the first rate threshold may be ⅕ or ⅖, and the second rate threshold may be 3/5 or 4/5. This can reduce decoding difficulty of the second device, and can ensure decoding accuracy. In addition, for data with a moderate encoding speed, for example, data whose encoding rate is greater than the first rate threshold and less than the second rate threshold, the first device may perform channel encoding on the data by using a structural code, to implement compatibility between the random code and the structural code. Based on this, a coding rule may be shown in the following Table 2:

TABLE 2

| Index | Encoding rate | Coding rule |
|---|---|---|
| 0 | R ≤ R1 | Random code |
| 1 | R1 < R < R2 | Structural code |
| 2 | R ≥ R2 | Random code |

R is the encoding rate for channel encoding, R1 is the first rate threshold, and R2 is the second rate threshold.

Optionally, in a fifth application scenario of the foregoing embodiment, the first device may determine, based on a service type, whether to use a random code to perform channel encoding or to use a structural code to perform channel encoding. For example, if the service type is a privacy service, channel encoding is performed by using the random code to improve communication security. Alternatively, if the service type is a normal service or a non-privacy service, channel encoding is performed by using the structural code, to improve decoding efficiency. Based on this, a coding rule may be shown in the following Table 3:

TABLE 3

| Index | Service type | Coding rule |
|---|---|---|
| 0 | Normal service | Structural code |
| 1 | Privacy service | Random code |

It may be understood that content shown in the foregoing Table 1 to Table 3 is merely an example, and is not intended as a limitation. For example, the foregoing Tables 1 to 3 may form any combination. In addition, in a possible design solution, the second device may configure the foregoing Table 1 to Table 3 for the first device, so that the first device can perform channel encoding according to Table 1 to Table 3. Alternatively, the first device may configure the foregoing Table 1 to Table 3 for the second device, so that the second device can perform channel decoding according to Table 1 to Table 3.

The foregoing describes in detail the communication method provided in embodiments of this application with reference to FIG. 3. With reference to FIG. 4 to FIG. 6, the following describes in detail communication apparatuses configured to perform the communication method provided in embodiments of this application.

For example, FIG. 4 is a schematic diagram 1 of a structure of a communication apparatus according to an embodiment of this application. As shown in FIG. 4, a communication apparatus 400 includes a transceiver module 401 and a processing module 402. For ease of description, FIG. 4 shows only main components of the communication apparatus.

In some embodiments, the communication apparatus 400 is applicable to the communication system shown in FIG. 2, and perform functions of the first device in the method shown in FIG. 3.

The processing module 402 is configured to perform channel encoding on first data based on a generator matrix to obtain second data.

The transceiver module 401 is configured to send the second data to a second device. The generator matrix is determined based on one or more of the following: a channel encoding parameter, a parameter of the communication apparatus 400, or a parameter of the second device. At least some parameters in the generator matrix are determined based on a random seed, and the random seed is determined based on one or more of the following: the channel encoding parameter, the parameter of the communication apparatus 400, or the parameter of the second device.

In a possible design solution, the at least some parameters in the generator matrix are determined based on the random seed and a neural network.

In a possible design solution, the following relationship exists between the random seed and the channel encoding parameter, the parameter of the communication apparatus 400, and the parameter of the second device: seed=G[ƒ₁ (x), ƒ₂(y), ƒ₃(z)], where seed is the random seed, x is the parameter of the communication apparatus 400, y is the parameter of the second device, z is the channel encoding parameter, G is a first function, ƒ₁ is a second function, ƒ₂ is a third function, and ƒ₃ is a fourth function.

In a possible design solution, the at least some parameters are determined by processing the random seed according to one or more of the following algorithms: a square number algorithm or a chaos algorithm.

In a possible design solution, the generator matrix is a K*N matrix, K and N are positive integers, K is less than N, and a quantity of the at least some parameters is any one of K*(N−K), K*N, or N−K+1.

Optionally, the quantity of the at least some parameters is K*N. Alternatively, optionally, the quantity of the at least some parameters is K*(N−K), and K² parameters in the K*N parameters of the generator matrix other than the at least some parameters form an identity matrix. Alternatively, optionally, the quantity of the at least some parameters is N-K+1, and each row in the generator matrix includes the at least some parameters.

Further, any two rows in the generator matrix are different.

In a possible design solution, the parameter of the communication apparatus 400 may include one or more of the following: an identifier of the communication apparatus 400 or an address of the communication apparatus 400.

In a possible design solution, the parameter of the second device may include one or more of the following: an identifier of the second device or an address of the second device.

In a possible design solution, the channel encoding parameter may include one or more of the following items for channel encoding: a length of the first data, an encoding length, or an encoding rate.

Optionally, the encoding length for the channel encoding is greater than or equal to a first length threshold, or the encoding length for the channel encoding is less than or equal to a second length threshold, where the first length threshold is less than the second length threshold.

Optionally, the encoding rate for channel encoding is greater than or equal to a first rate threshold, or the encoding rate for channel encoding is less than or equal to a second rate threshold, where the first rate threshold is less than the second rate threshold.

In a possible design solution, the transceiver module 401 is further configured to: before the processing module 402 performs channel encoding on the first data based on the generator matrix to obtain the second data, receive configuration information from a third device. The configuration information includes one or more of the following: the generator matrix, the channel encoding parameter, the parameter of the communication apparatus 400, or the parameter of the second device.

Optionally, the transceiver module 401 may alternatively include a sending module and a receiving module (which are not shown in FIG. 4). The sending module is configured to implement a sending function of the communication apparatus 400, and the receiving module is configured to implement a receiving function of the communication apparatus 400.

Optionally, the communication apparatus 400 may further include a storage module (which is not shown in FIG. 4), and the storage module stores a program or instructions. When the processing module executes the program or the instructions, the communication apparatus 400 may perform the functions of the first device in the method shown in FIG. 3.

It should be understood that the processing module in the communication apparatus 400 may be implemented by a processor or a processor-related circuit component, and may be a processor or a processing unit. The transceiver module may be implemented by a transceiver or a transceiver-related circuit component, and may be a transceiver or a transceiver unit.

It should be noted that the communication apparatus 400 may be a terminal or a network device, or may be a chip (system) or another component or assembly that may be disposed in a terminal or a network device, or may be an apparatus that includes a terminal or a network device. This is not limited in this application.

In addition, for technical effect of the communication apparatus 400, refer to the corresponding technical effect in the method shown in FIG. 3. Details are not described herein again.

In some other embodiments, the communication apparatus 400 is applicable to the communication system shown in FIG. 2, and perform the functions of the second device in the method shown in FIG. 3.

The transceiver module 401 is configured to receive second data from a first device.

The processing module 402 is configured to decode the second data based on a generator matrix to obtain first data. The generator matrix is determined based on one or more of the following: a channel encoding parameter, a parameter of the first device, or a parameter of the communication apparatus 400. At least some parameters in the generator matrix are determined based on a random seed, and the random seed is determined based on one or more of the following: the channel encoding parameter, the parameter of the first device, or the parameter of the communication apparatus 400.

In a possible design solution, the at least some parameters in the generator matrix are determined based on the random seed and a neural network.

In a possible design solution, the following relationship exists between the random seed and the channel encoding parameter, the parameter of the first device, and the parameter of the communication apparatus 400: seed=G[ƒ₁(x), ƒ₂(y), ƒ₃(z)], where seed is the random seed, x is the parameter of the first device, y is the parameter of the communication apparatus 400, z is the channel encoding parameter, G is a first function, ƒ₁ is a second function, ƒ₂ is a third function, and ƒ₃ is a fourth function.

In a possible design solution, the at least some parameters are determined by processing the random seed according to one or more of the following algorithms: a square number algorithm or a chaos algorithm.

In a possible design solution, the generator matrix is a K*N matrix, K and N are positive integers, K is less than N, and a quantity of the at least some parameters is any one of K*(N−K), K*N, or N−K+1.

Optionally, the quantity of the at least some parameters is K*N. Alternatively, optionally, the quantity of the at least some parameters is K*(N−K), and K² parameters in the K*N parameters of the generator matrix other than the at least some parameters form an identity matrix. Alternatively, optionally, the quantity of the at least some parameters is N−K+1, and each row in the generator matrix includes the at least some parameters.

Further, any two rows in the generator matrix are different.

In a possible design solution, the parameter of the first device may include one or more of the following: an identifier of the first device or an address of the first device.

In a possible design solution, the communication apparatus 400 may include one or more of the following: an identifier of the communication apparatus 400 or an address of the communication apparatus 400.

In a possible design solution, the channel encoding parameter may include one or more of the following items for channel encoding: a length of the first data, an encoding length, or an encoding rate.

Optionally, the encoding length for the channel encoding is greater than or equal to a first length threshold, or the encoding length for the channel encoding is less than or equal to a second length threshold, where the first length threshold is less than the second length threshold.

Optionally, the encoding rate for channel encoding is greater than or equal to a first rate threshold, or the encoding rate for channel encoding is less than or equal to a second rate threshold, where the first rate threshold is less than the second rate threshold.

In a possible design solution, the transceiver module 401 is further configured to: before the processing module 402 decodes the second data based on the generator matrix to obtain the first data, receive configuration information from a third device. The configuration information includes one or more of the following: the generator matrix, the channel encoding parameter, the parameter of the first device, or the parameter of the communication apparatus 400.

Optionally, the transceiver module 401 may alternatively include a sending module and a receiving module (which are not shown in FIG. 4). The sending module is configured to implement a sending function of the communication apparatus 400, and the receiving module is configured to implement a receiving function of the communication apparatus 400.

Optionally, the communication apparatus 400 may further include a storage module (which is not shown in FIG. 4), and the storage module stores a program or instructions. When the processing module executes the program or the instructions, the communication apparatus 400 may perform the functions of the second device in the method shown in FIG. 3.

It should be understood that the processing module in the communication apparatus 400 may be implemented by a processor or a processor-related circuit component, and may be a processor or a processing unit. The transceiver module may be implemented by a transceiver or a transceiver-related circuit component, and may be a transceiver or a transceiver unit.

It should be noted that the communication apparatus 400 may be a terminal or a network device, or may be a chip (system) or another component or assembly that may be disposed in a terminal or a network device, or may be an apparatus that includes a terminal or a network device. This is not limited in this application.

In addition, for technical effect of the communication apparatus 400, refer to the corresponding technical effect in the method shown in FIG. 3. Details are not described herein again.

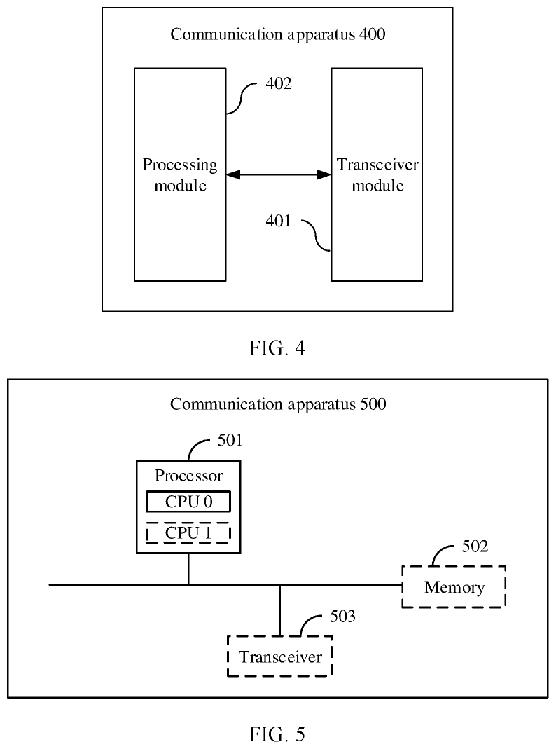

For example, FIG. 5 is a schematic diagram 2 of a structure of a communication apparatus according to an embodiment of this application. The communication apparatus may be a terminal device or a network device, or may be a chip (system) or another component or assembly that may be disposed in a terminal device or a network device. As shown in FIG. 5, a communication apparatus 500 may include a processor 501. Optionally, the communication apparatus 500 may further include a memory 502 and/or a transceiver 503. The processor 501 is coupled to the memory 502 and the transceiver 503, for example, may be connected to the memory 502 and the transceiver 503 through a communication bus.

The following describes each component of the communication apparatus 500 in detail with reference to FIG. 5.

The processor 501 is a control center of the communication apparatus 500, and may be one processor, or may be a collective name of a plurality of processing elements. For example, the processor 501 is one or more central processing units (CPUs), may be an application-specific integrated circuit (ASIC), or is configured as one or more integrated circuits for implementing embodiments of this application, for example, one or more microprocessors (DSPs) or one or more field programmable gate arrays (FPGAs).

Optionally, the processor 501 may execute various functions of the communication apparatus 500 by running or executing a software program stored in the memory 502 and invoking data stored in the memory 502.

In specific implementation, in an embodiment, the processor 501 may include one or more CPUs, for example, a shown CPU 0 and a shown CPU 1.

In specific implementation, in an embodiment, the communication apparatus 500 may alternatively include a plurality of processors. Each of the processors may be a single-core (single-CPU) processor, or may be a multi-core (multi-CPU) processor. The processor herein may be one or more devices, circuits, and/or processing cores configured to process data (for example, computer program instructions).

The memory 502 is configured to store the software program for executing the solutions of this application, and the processor 501 controls execution of the software program. For a specific implementation, refer to the foregoing method embodiment. Details are not described herein again.

Optionally, the memory 502 may be a read-only memory (ROM) or another type of static storage device capable of storing static information and instructions, or may be a random access memory (RAM) or another type of dynamic storage device capable of storing information and instructions, or may be an electrically erasable programmable read-only memory (EEPROM), a compact disc read-only memory (CD-ROM) or other compact disc storage, optical disc storage (including a compressed optical disc, a laser disc, an optical disc, a digital versatile disc, a Blu-ray disc, or the like), a magnetic disk storage medium or another magnetic storage device, or any other medium capable of carrying or storing expected program code in a form of an instruction or a data structure and capable of being accessed by a computer. However, this is not limited herein. The memory 502 may be integrated with the processor 501, or may exist independently, and is coupled to the processor 501 through an interface circuit (which is not shown in FIG. 5) of the communication apparatus 500. This is not limited in this embodiment of this application.

The transceiver 503 is configured to communicate with another communication apparatus. For example, the communication apparatus 500 is a terminal device, and the transceiver 503 may be configured to communicate with a network device or communicate with another terminal device. For another example, the communication apparatus 500 is a network device, and the transceiver 503 may be configured to communicate with a terminal device or communicate with another network device.

Optionally, the transceiver 503 may include a receiver and a transmitter (which are not separately shown in FIG. 5). The receiver is configured to implement a receiving function, and the transmitter is configured to implement a sending function.

Optionally, the transceiver 503 may be integrated with the processor 501, or may exist independently, and is coupled to the processor 501 through the interface circuit (which is not shown in FIG. 5) of the communication apparatus 500. This is not limited in this embodiment of this application.

It should be noted that the structure of the communication apparatus 500 shown in FIG. 5 does not constitute a limitation on the communication apparatus. An actual communication apparatus may include more or fewer components than those shown in the figure, or combine some components, or have different component arrangement.

In addition, for technical effect of the communication apparatus 500, refer to the technical effect of the communication method in the foregoing method embodiment. Details are not described herein again.

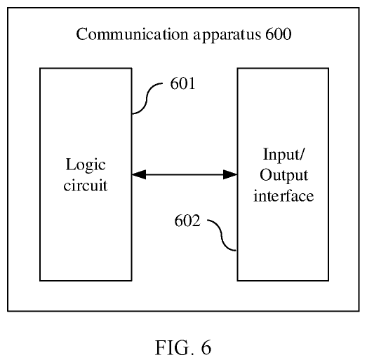

For example, FIG. 6 is a schematic diagram 3 of a structure of a communication apparatus according to an embodiment of this application. The communication apparatus may be a terminal device or a network device, or may be a chip (system) or another component or assembly that may be disposed in a terminal device or a network device. As shown in FIG. 6, a communication apparatus 600 may include a logic circuit 601 and an input/output interface 602. The input/output interface 602 is configured to receive code instructions and transmit the code instructions to the logic circuit 601, and the logic circuit 601 is configured to run the code instructions to perform the method as described above.

In addition, for technical effect of the communication apparatus 600, refer to the technical effect of the communication method in the foregoing method embodiment. Details are not described herein again.

An embodiment of this application provides a communication system. The communication system includes one or more terminal devices and one or more network devices.

It should be understood that the processor in embodiments of this application may be a CPU, or the processor may be another general-purpose processor, a DSP, an ASIC, a field programmable gate array FPGA or another programmable logic device, a discrete gate or a transistor logic device, a discrete hardware component, or the like. The general-purpose processor may be a microprocessor, or the processor may be any conventional processor or the like.

It may be further understood that the memory in embodiments of this application may be a volatile memory or a nonvolatile memory, or may include a volatile memory and a nonvolatile memory. The nonvolatile memory may be a ROM, a programmable read-only memory (PROM), an erasable programmable read-only memory (EPROM), an EEPROM, or a flash memory. The volatile memory may be a RAM, and serves as an external cache. Through example but not limitative description, many forms of RAMs may be used, for example, a static random access memory (SRAM), a dynamic random access memory (DRAM), a synchronous dynamic random access memory (SDRAM), a double data rate synchronous dynamic random access memory (DDR SDRAM), an enhanced synchronous dynamic random access memory (ESDRAM), a synchlink dynamic random access memory (SLDRAM), and a direct rambus random access memory (DR RAM).

All or some of the foregoing embodiments may be implemented by using software, hardware (for example, a circuit), firmware, or any combination thereof. When software is used to implement embodiments, the foregoing embodiments may be implemented completely or partially in a form of a computer program product. The computer program product includes one or more computer instructions or computer programs. When the program instructions or the computer programs are loaded and executed on a computer, the procedures or functions according to embodiments of this application are all or partially generated. The computer may be a general-purpose computer, a special-purpose computer, a computer network, or another programmable apparatus. The computer instructions may be stored in a computer-readable storage medium or may be transmitted from a computer-readable storage medium to another computer-readable storage medium. For example, the computer instructions may be transmitted from a website, computer, server, or data center to another website, computer, server, or data center in a wired (for example, infrared, radio, or microwave) manner. The computer-readable storage medium may be any usable medium accessible by a computer, or a data storage device, such as a server or a data center, integrating one or more usable media. The usable medium may be a magnetic medium (for example, a floppy disk, a hard disk, or a magnetic tape), an optical medium (for example, a DVD), or a semiconductor medium. The semiconductor medium may be a solid-state drive.

It should be understood that the term “and/or” in this specification describes only an association relationship between associated objects and represents that three relationships may exist. For example, A and/or B may represent the following three cases: Only A exists, both A and B exist, and only B exists, where A and B may be singular or plural. In addition, the character “/” in this specification usually indicates an “or” relationship between the associated objects, but may also indicate an “and/or” relationship. For details, refer to the context for understanding.

In this application, “at least one” means one or more, and “a plurality of” means two or more. “At least one of the following items (pieces)” or a similar expression thereof refers to any combination of these items, including any combination of singular items (pieces) or plural items (pieces). For example, at least one of a, b, or c may indicate: a, b, c, a-b, a-c, b-c, or a-b-c, where a, b, and c may be singular or plural.

It should be understood that sequence numbers of the foregoing processes do not mean execution orders in various embodiments of this application. The execution orders of the processes should be determined based on functions and internal logic of the processes, and should not be construed as any limitation on the implementation processes of embodiments of this application.

A person of ordinary skill in the art may be aware that, in combination with the examples described in embodiments disclosed in this specification, units and algorithm steps can be implemented by electronic hardware or a combination of computer software and electronic hardware. Whether the functions are performed by hardware or software depends on particular applications and design constraints of the technical solutions. A person skilled in the art may use different methods to implement the described functions for each particular application, but it should not be considered that the implementation goes beyond the scope of this application.

It may be clearly understood by a person skilled in the art that, for the purpose of convenient and brief description, for a detailed working process of the foregoing system, apparatus, and unit, refer to a corresponding process in the foregoing method embodiment. Details are not described herein again.

In the several embodiments provided in this application, it should be understood that the disclosed system, apparatus, and method may be implemented in other manners. For example, the described apparatus embodiment is merely an example. For example, division into the units is merely logical function division and may be other division in actual implementation. For example, a plurality of units or components may be combined or integrated into another system, or some features may be ignored or not performed. In addition, the displayed or discussed mutual couplings or direct couplings or communication connections may be implemented through some interfaces. The indirect couplings or communication connections between the apparatuses or units may be implemented in electronic, mechanical, or other forms.

The units described as separate parts may or may not be physically separate, and parts displayed as units may or may not be physical units, may be located in one location, or may be distributed on a plurality of network units. Some or all of the units may be selected based on actual requirements to achieve the objectives of the solutions of embodiments.

In addition, functional units in embodiments of this application may be integrated into one processing unit, each of the units may exist alone physically, or two or more units may be integrated into one unit.

When the functions are implemented in a form of a software functional unit and sold or used as an independent product, the functions may be stored in a computer-readable storage medium. Based on such an understanding, the technical solutions of this application essentially, or the part contributing to the communication, or some of the technical solutions may be implemented in a form of a software product. The computer software product is stored in a storage medium, and includes several instructions for instructing a computer device (which may be a personal computer, a server, or a network device) to perform all or some of the steps of the method described in embodiments of this application. The foregoing storage medium includes any medium that can store program code, for example, a USB flash drive, a removable hard disk, a ROM, a RAM, a magnetic disk, or an optical disc.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

What is claimed is:

1. A communication method, comprising:
determining a generator matrix, wherein:
at least some parameters in the generator matrix are determined based on a random seed, and the random seed is determined based on one or more of the following: a channel encoding parameter, a parameter of the first device, or a parameter of a second device; or
the generator matrix is determined based on one or more of the following: the channel encoding parameter, the parameter of the first device, or the parameter of the second device;
performing, by a first device, channel encoding on first data based on the generator matrix to obtain second data; and
sending, by the first device, the second data to the second device.

2. The method according to claim 1, wherein before the performing, by the first device, channel encoding on first data based on the generator matrix to obtain second data, the method further comprises:
receiving, by the first device, configuration information from a third device, wherein
the configuration information comprises one or more of the following: the generator matrix, the channel encoding parameter, the parameter of the first device, or the parameter of the second device.

3. The method according to claim 1, wherein the at least some parameters in the generator matrix are determined based on the random seed and a neural network.

4. The method according to claim 1, wherein at least some parameters in the generator matrix are determined based on the random seed, and the following relationship exists between the random seed and the parameter of the first device, the channel encoding parameter, and the parameter of the second device:
seed=G[ƒ₁(x),ƒ₂(y),ƒ₃(z)], wherein
seed is the random seed, x is the parameter of the first device, y is the parameter of the second device, z is the channel encoding parameter, G is a first function, ƒ₁ is a second function, ƒ₂ is a third function, and ƒ₃ is a fourth function.

5. The method according to claim 1, wherein the at least some parameters are determined by processing the random seed according to one or more of the following algorithms: a square number algorithm or a chaos algorithm.

6. The method according to claim 1, wherein the generator matrix is a K*N matrix, K and N are positive integers, K is less than N, and a quantity of the at least some parameters is any one of the following: K*(N−K), K*N, or N−K+1.

7. The method according to claim 6, wherein the quantity of the at least some parameters is K*N, and any two rows in the generator matrix are different.

8. The method according to claim 6, wherein the quantity of the at least some parameters is K*(N−K), K² parameters in the K*N parameters of the generator matrix other than the at least some parameters form an identity matrix, and any two rows in the generator matrix are different.

9. The method according to claim 6, wherein the quantity of the at least some parameters is N−K+1, each row in the generator matrix comprises the at least some parameters, and any two rows in the generator matrix are different.

10. The method according to claim 1, wherein the parameter of the first device comprises one or more of the following: an identifier of the first device or an address of the first device.

11. The method according to claim 1, wherein the parameter of the second device comprises one or more of the following: an identifier of the second device or an address of the second device.

12. The method according to claim 1, wherein the channel encoding parameter comprises one or more of the following items for channel encoding: a length of the first data, an encoding length, or an encoding rate.

13. The method according to claim 12, wherein the encoding length is greater than or equal to 16 bits, or the encoding length is less than or equal to 128 bits.

14. The method according to claim 12, wherein the encoding rate is greater than or equal 1/5, or the encoding rate is less than or equal to 4/5.

15. A communication method, comprising:
determining a generator matrix, wherein:
at least some parameters in the generator matrix are determined based on a random seed, and the random seed is determined based on one or more of the following: a channel encoding parameter, a parameter of the first device, or a parameter of a second device; or
the generator matrix is determined based on one or more of the following: the channel encoding parameter, the parameter of the first device, or the parameter of the second device;
receiving, by a second device, second data from a first device; and
decoding, by the second device, the second data based on the generator matrix to obtain first data.

16. The method according to claim 15, further comprising:
decoding, by the second device, the second data based on a generator matrix to obtain first data; and
before the decoding, receiving, by the second device, configuration information from the third device, wherein the configuration information comprises one or more of the following: the generator matrix, the channel encoding parameter, the parameter of the first device, or the parameter of the second device.

17. A first device, comprising at least one non-transitory memory and at least one processor, wherein the at least one non-transitory memory is configured to store computer instructions, and the at least one processor is configured to execute the computer instructions, so that the first device is enabled to:
determine a generator matrix, wherein:
at least some parameters in the generator matrix are determined based on a random seed, and the random seed is determined based on one or more of the following: a channel encoding parameter, a parameter of the first device, or a parameter of a second device; or
the generator matrix is determined based on one or more of the following: the channel encoding parameter, the parameter of the first device, or the parameter of the second device;
perform channel encoding on first data based on the generator matrix to obtain second data; and
send the second data to the second device.

18. The apparatus according to claim 17, wherein the first device is further enabled to: before performing channel encoding on the first data based on the generator matrix to obtain the second data, receive configuration information from a third device, wherein the configuration information comprises one or more of the following: the generator matrix, the channel encoding parameter, the parameter of the first device, or the parameter of the second device.

19. The first device according to claim 17, wherein the at least some parameters in the generator matrix are determined based on the random seed and a neural network.

20. The first device according to claim 17, wherein at least some parameters in the generator matrix are determined based on the random seed, and the following relationship exists between the random seed and the parameter of the first device, the channel encoding parameter, and the parameter of the second device:
seed=G[ƒ₁(x),ƒ₂(y),ƒ₃(z)], wherein
seed is the random seed, x is the parameter of the first device, y is the parameter of the second device, z is the channel encoding parameter, G is a first function, ƒ₁ is a second function, ƒ₂ is a third function, and ƒ₃ is a fourth function.
